(19) United States
(12) Patent Application Publication
(10) Pub. No.: US 2004/0187766 A1
(43) Pub. Date: Sep. 30, 2004

(54) Method of fabricating monocrystalline crystals

(76) Inventor: Fabrice Letertre, Grenoble (FR)

Correspondence Address: WINSTON & STRAWN, PATENT DEPARTMENT, 1400 L STREET, N.W., WASHINGTON, DC, 20005-3502, US

(21) Appl. No.: 10/716,451

(22) Filed: Nov. 20, 2003

(30) Foreign Application Priority Data
Mar. 31, 2003 (FR) 0303928

(51) Int. Cl. C30B 1/00

(52) U.S. Cl. 117/11

(57) ABSTRACT

A method of producing a crystal formed from a first monocrystalline material. The preferred method includes assembling a first substrate with at least one film or at least one layer formed from a second monocrystalline material, and growing the first material on the film or thin layer. The invention also provides a corresponding crystal.

### FIELD OF THE INVENTION

The present invention relates to the field of fabricating monocrystalline crystals preferably for use in microelectronics, optoelectronics, optics, or power electronics.

### BACKGROUND OF THE INVENTION

Light emitting diode (LED) or laser diode type optoelectronic components on silicon carbide (“SiC”) substrates, which emit in the short wavelengths of the visible spectrum (blue, ultraviolet), are currently produced on substrates with a diameter limited to 2 inches. The density of defects (of the micropipe type) of the SiC substrates is relatively high, on the order of about 100 defects cm⁻². These factors limit the fabrication yields of such components.

Power electronic components such as Schottky diodes or, metal oxide semiconductor (MOS), or power field effect transistors (FETs) are currently produced on substrates with a diameter up to 2 inches. The density of defects (of the micropipe type) of the best SiC substrates produced today is also fairly high, up to about 15 defects cm⁻², which also limits the fabrication yields of such components. Further, the many typical fabrication facilities of this type of component typically only accept substrates with a minimum diameter of 100 mm. Thus the diameter of available SiC wafers (2 inches) is currently insufficient to trigger significant industrial activity.

In SiC, defects are of the “micropipe” type, as described for example in the article by V. Tsvetkov et al in Materials Science Forum, Vol 264-268, part 1, pages 3-8, 1998 entitled “SiC seeded boule growth”. Thus, with SiC, there is a problem with producing substrates with micropipe densities of less than 1 cm⁻² or in the range 1 cm⁻² to 10 cm⁻².

For GaN and AlN, on the other hand, dislocation density is the critical factor. A GaN substrate obtained by thick epitaxy has a typical dislocation density of the order of 10⁸ cm⁻². The best currently available substrates of those materials have dislocation densities of the order of 10⁵ cm⁻² to 10⁶ cm⁻². Thus, there is a problem with producing GaN or AlN substrates with dislocation densities of less than 10⁴ cm⁻². Those substrates are used in the fabrication of laser diodes or long-life power LEDs.

More generally, there is a problem with producing crystals, in particular of SiC, GaN, or AlN, and especially crystals of large diameter and high purity. A technique for fabricating SiC by very high temperature using sublimation temperature above 2000° C.) is known. A further recent technique is high temperature epitaxial growth (high temperature chemical vapor deposition, HTCVD, carried out between 1800° C. and 2000° C.). The sublimation technique is also used for AlN and GaN, but SiC is several years ahead in this regard. Finally for GaN, thick epitaxial growth (hydride vapor phase epitaxy, “HVPE”) is employed to produce self-supported GaN substrates. In all of those techniques, producing a large diameter crystal is either very difficult or intrinsically impossible.

In particular, high temperature sublimation suffers from the following problems when growing large crystals. To widen a crystal using this technique, radial temperature gradients between the center of the crystal and its edge have to be controlled. The literature, and in particular the article by C. Moulin et al “SiC single crystal growth by sublimation: experimental and numerical results” in Material Science Forums, vol 353. 356 (2001), pp 7-10, describes many correlations between temperature gradients and crystal defects and the stresses across the crystal diameter. That control is technologically very difficult as it has to be of the order of a few degrees C. for a crystal heated to more than 2000° C. Further, when a crystal is to be enlarged, it is not produced in the form of a cylinder, but rather in the form of a truncated cone.

A further technique has been developed that can obtain straight crystals by controlling thermal effects (see, for example, Y. Kitou et al, “Flux controlled sublimation growth by an inner guide tube”, Material Science Forum, vol 383-393 (2002), pp 83-86). However, the crystal diameters obtained are small and they cannot be made wider using that technique.

Thus, a method is needed to produce wide or large area crystals having low defects, and the present invention now satisfies this need.

### SUMMARY OF THE INVENTION

The invention is directed to a method of producing a crystal that can be used, for example, in microelectronics, optoelectronics, optics, or power electronics. In the preferred method, a plurality of layer segments are arranged and associated with a first substrate to form an assembled layer that comprises the segments. The layer segments are made of a first monocrystalline material. A layer of a monocrystalline material is grown on the assembled layer by using the assembled layer as seed material. The grown monocrystalline material in the preferred embodiment is the same as the first monocrystalline material, although a grown monocrystalline material that is different from the first monocrystalline material but compatible therewith can be used instead.

The first layer segments may comprise thin films, and the first substrate preferably has a face on which the assembled layer is disposed. This preferred dimensions of the face include a diameter of at least about 100 mm and a surface area of at least about 75 cm². The layer segments are preferably associated with the first substrate by molecular bonding.

A donor substrate made of the first material can be associated with the first substrate and then thinned to provide the arranged layer segments that are associated with the first substrate. A region of weakness can be formed in the donor substrate, and the layer segment of the donor substrate can be detached from the donor substrate that is associated with the first substrate at the region of weakness to thin the donor substrate. The region of weakness can be produced, for example, by forming a porous zone in the donor substrate, or by implanting atomic species into the donor substrate. Also, the donor substrate can be thinned by polishing or etching.

In one environment, the layer segments can be associated with a second substrate, and arranged with and associated with the first substrate while they are associated with the second substrate. The second substrates can be removed from the layer segments once the segments are associated with the first substrate. A preferred material for the second substrate is silicon dioxide.

The grown layer can be grown by several methods such as sublimation or high temperature thick epitaxy. The first microcrystalline material in one environment comprises silicon carbide with a micropipe density of less than about 10 cm⁻². This first material can alternatively comprise aluminum nitride or gallium nitride having a dislocation density of less than about a 10⁴ cm⁻². In one embodiment, the first monocrystalline material compresses silicon carbide polytype 6H, 4H, or 3C. A preferred first substrate comprises graphite.

Preferably, the grown layer of monocrystalline material provides a thickness between about 15 μm and 10 mm. This thickness of the assembled layer in a preferred embodiment is between about 0.1 μm and 1.5 μm. Also, the arranged layer segments preferably have the same crystal orientation to facilitate the growing of the monocrystalline growth layer. A preferred embodiment of a crystal made according to the invention encompasses a circular region with a diameter of at least about 100 mm and a thickness of less than about 10 mm, with the circular region being measured on the monocrystalline material, even if the crystal has a non-circular shape. Preferably, the thickness of the crystal is less than about 1 mm and at least about 10 μm. One embodiment in the monocrystalline material is silicon carbide with a micropipe density of less than about 1 cm⁻². The monocrystalline material can be silicon carbide polytype 6H, 4H, or 3C, or, for example, an element of nitride or gallium nitride with a dislocation density of less than about 10⁴ cm⁻².

A preferred crystalline wafer constructed according to the present invention includes a first substrate and an assembled layer that includes a plurality of layer segments arranged and associated with a first substrate in a same crystal orientation for growing thereon a grown layer of monocrystalline material. The preferred layer segments comprise silicon carbide, aluminum nitride, gallium nitrite, aluminum gallium nitride, or indium gallium nitrite. Also, the preferred wafer additionally includes a grown layer of monocrystalline material that is grown on the first substrate.

### BRIEF DESCRIPTION OF THE DRAWINGS

FIG. 1 shows a first embodiment of a method of producing a crystal according to the present invention;

FIG. 2 shows a second embodiment thereof;

FIGS. 3-4C show certain steps in carrying out a preferred method of the invention;

FIG. 5 shows a crystal growth step; and

FIG. 6 shows an example of a crystal obtained by the method of the invention.

### DETAILED DESCRIPTION OF THE PREFERRED EMBODIMENTS

The present invention relates to the fabrication of large diameter crystals, preferably with low defect densities. The present invention also relates to the fabrication of crystals of any diameter, in particular less than 100 mm, with a low defect density.

The invention can employ materials such as silicon carbide (SiC), aluminum nitride (AlN) and gallium nitride (GaN). One application of the invention concerns the field of electronic and optoelectronic components using monocrystalline substrates with low defect density as the base substrate in their fabrication.

In a first aspect, the invention provides a method of producing a crystal formed from a first monocrystalline material, which can comprise:

a step of assembling a first substrate with at least one film or layer of a first monocrystalline material or of a second monocrystalline material that is compatible with the first material; and

a step of growing said first material on the film or thin layer.

Preferably, the diameter of the first substrate is 100 mm or more. A large diameter crystal can be obtained that has a maximum diameter or dimension of 100 mm or more, more preferably in the range of about 100 mm to 300 mm, and most preferably in the range of 100 mm to 150 mm or 200 mm.

To produce a growth seed of large surface area, it is possible to assemble or juxtapose a plurality of thin films on the first substrate. The assembly step can be carried out by bonding at least one film or at least one monocrystalline material layer on the first substrate.

The preferred method may comprise assembling the first substrate, with a crystal of monocrystalline material, then thinning the crystal, with the thinning possibly being carried out by prior formation of a layer or a zone of weakness in the crystal, followed by detaching a portion of the crystal along the zone of weakness, or by polishing or engraving. Alternatively, the assembly step can comprise assembling a thin film on a second substrate, assembling the first substrate with the assembly that includes the thin film and the second substrate, and detaching the second substrate and the thin film or removing the second substrate therefrom.

The growth employed in the preferred embodiment can be of the high temperature thick epitaxial type or by sublimation. The growth can produce a crystalline material with a thickness in the range several tens of micrometers (μm) to several mm.

The invention also provides a crystal of monocrystalline material, with a maximum dimension or diameter of 100 mm or more and/or with a micropipe density of less than 1 cm⁻², such as for SiC, in particular of polytype 6H or 4H or 3C, or with dislocation densities of less than 10³ cm⁻² or 10⁴ cm⁻², such as for AlN or GaN. Such a crystal can have a thickness, for example, between about 1 mm and 10 mm, more preferably between about 100 μm and 1 mm, and most preferably between about 100 μm and 500 μm. The invention also provides a method of epitaxially growing a material, in which the material is grown on the crystal. The thickness is greater than about 0.1 μm or 0.3 μm and less than about 0.7 μm or 1.5 μm.

A first implementation of the invention provides a method of fabricating SiC crystals. However, the invention is also applicable to other materials, such as AlN or GaN.

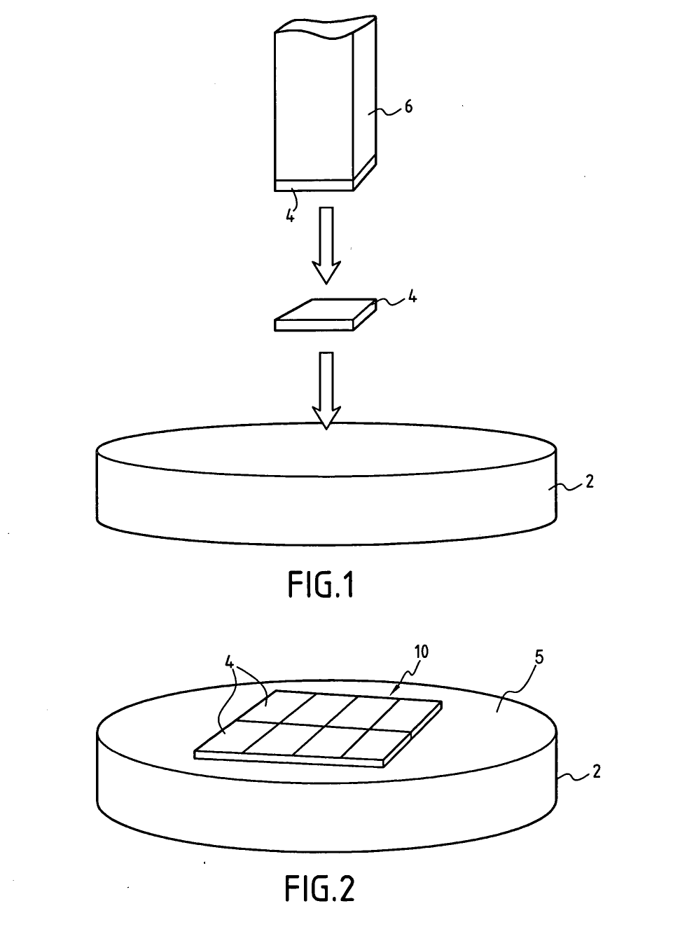

As shown in FIG. 1, a film 4 of monocrystalline SiC that is thin, for example 0.5 μm thick or in the range 0.1 μm to 1 μm or to 2 μm, is removed from a source donor substrate 6. Preferably the film 4 has a low defect or micropipe density, for example less than about 1 cm⁻² or in the range of about 1 cm⁻² to 10 cm⁻². The thin film 4 is then transferred, for example by bonding, to a support substrate 2, which can have a diameter of more than 100 mm.

For SiC, and also for AlN and GaN, the support substrate 2 can be formed from graphite, and bonding can be carried out with a refractory adhesive, such as a graphite adhesive. It is possible to bond either the Si face or the C face of the SiC crystal to the graphite.

If the donor substrate 6 is not enough to include a circular face to be bonded with a diameter of less than 100 mm, or another preselected shape of minimum size, it is possible, as illustrated in FIG. 2, to carry out several removal and transfer steps on the same substrate 2 to cover the support substrate bonding surfaces with an assembly 10 of transferred films 4 over an area which may be square or substantially circular or some other shape. The cumulative area covered is preferably at least equivalent to that covered by a circular substrate of the desired diameter, for example more than 100 mm. Thus, a plurality of thin films can be arranged in an assembly side by side, for example in the manner of a jigsaw puzzle to produce a square, rectangle, or other shape. Preferably, the assembly 10 covers an area of the substrate 2 of at least 75 cm² or 80 cm², for example, to provide a crystal at least 100 mm in diameter or in a maximum transverse dimension. The area covered by the arrangement is preferably in the range 75 cm² to 320 cm² or preferably up to 500 cm² to produce a crystal with a diameter or a maximum dimension in the range of 100 mm to 150 mm, up to about 200 mm, or up to about 300 mm or even more where possible.

Preferably, care is taken to ensure that the crystal orientation of these various transferred crystals is such that overall, the covered surface has a single surface crystal orientation. The crystal defect density on the assembly produced is also preferably substantially homogeneous over the whole of the surface that has been formed.

Thus, the invention can produce a monocrystalline crystal by transferring to a support part 2, which is intended to be placed in a growth furnace, one or more thin monocrystalline films 4 with a thickness, for example, on the order of a few tens of μm. The preferred range of the thickness is between about 0.3 μm and 0.7 μm. The produced film is preferably of very high quality, this quality being, in part, a function of the initial quality of the source substrate 6.

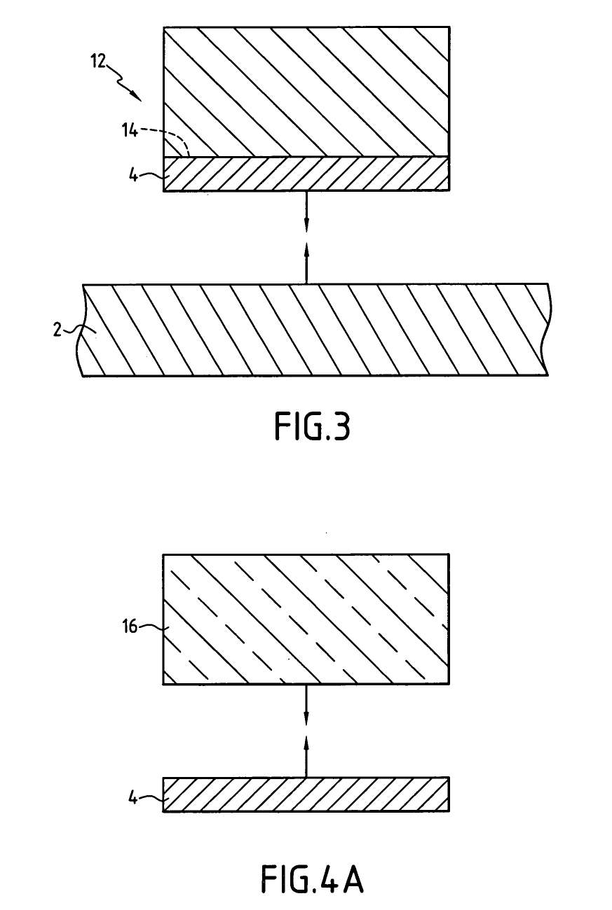

As shown in FIG. 3, the thin film 4 can be transferred to the substrate 2 using a crystal 12 in which the region of weakness 14, preferably extending generally planarly, has been formed in advance, for example by hydrogen and/or helium ion implantation. Assembly of the crystal filing and the first substrate 2 is followed by thinning. A treatment that can cause fracture along the plane of weakness, and thus thinning, has been described, for example, in the article by A. J. Auberton-Hervé et al entitled “Why can Smart Cut change the future of microelectronics?” in the International Journal of High Speed Electronics and Systems, vol 10, No 1, 2000, p 131-146.

A region of weakness can be formed using methods other than ion implantation. A layer of porous silicon can be produced as described in the article by K. Sataguchi et al, “Eltran by splitting porous Si layers”, Proc. of the 9^{th} Int. Symp. on Silicon-on-Insulator Tech. and Device, 99-3, The Electrochemical Society, Seattle, pp 117-121, 1999. That technique can be applied to SiC, GaN, AlN. It is alternatively possible to carry out thinning without employing a region of weakness, for example by polishing or etching.

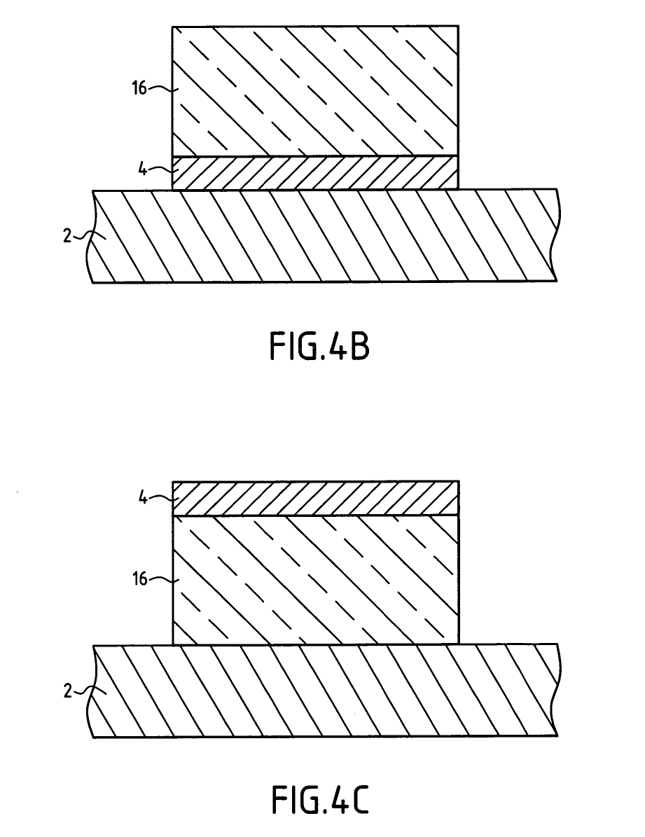

As shown in FIGS. 4A and 4B, the thin film 4 can also be transferred to the substrate 2 using a second substrate 16 and then associating a thin film 4 to the second substrate 16 (FIG. 4A), for example by molecular bonding. This type of bonding has been described, for example, in the work by Q. T. Yong and U. Gösele, “Semiconductor wafer bonding” (Science and Technology), Wiley Interscience publications. In the case of SiC, this second substrate can be formed from silicon dioxide; thus, a SiCOI (SiC on insulator) type structure is temporarily formed.

The bonded layers are then joined to the first substrate 2 (FIG. 4B), for example by bonding using a graphite adhesive. The second substrate 16 is then detached from the thin film 4 by unbonding the substrate 16 and the thin film 4 along the bonding interface that connects them, or can be removed by polishing and/or chemical attack.

In an alternative embodiment, shown in FIG. 4C, the thin film 4 is transferred to the second substrate 16, but the second substrate 16 is then placed on the substrate 2 as shown in the figure. Thus, there is no longer any need to detach the substrate 16 from the thin film 4.

Transfer can thus be carried out, for example, by bonding a crystal that has been implanted in advance with hydrogen ions, for example, or other atomic species, or in which a porous layer has been formed, and transferring a thin film after fracture annealing, or else by bonding a thin film that has already been bonded and transferred to a temporary substrate and which, after bonding to the support part, may be completely removed to leave only the thin film if the film is positioned against the support part itself. It is also possible to transfer thicker layers rather than thin layers onto a substrate 2, as shown in FIG. 2. In this case, there may be no need to thin a crystal such as the crystal 12 or to remove a second substrate such as the substrate 16.

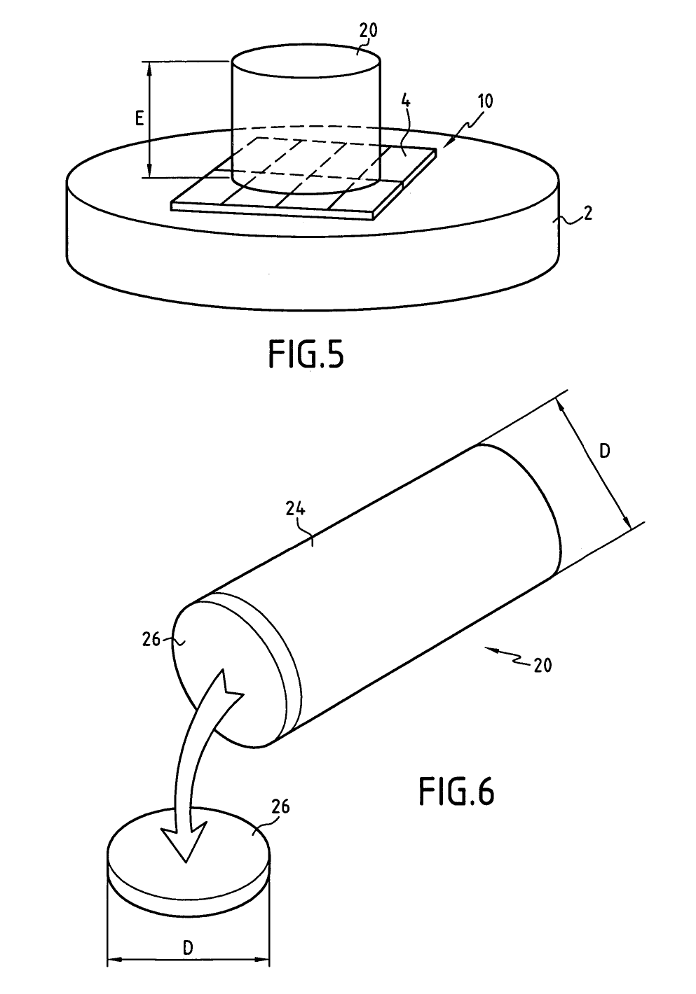

When thin films are used, however, several of the films can be taken from the same wafer or from the same very high quality source substrate with the same crystal orientation properties. Once covered with thin films, growth can be initiated after placing the support part with its covering of films in a growth apparatus. Subsequently (FIG. 5), an ingot 20 can be grown by sublimation or by high temperature thick epitaxy onto the assembly 10. The thick epitaxy is preferably from about 10 μm to 500 μm, but typically will be between about 200 μm and 400 μm. For AlN and GaN, growth can be carried out on a thin film of SiC. Although the materials are different, they are mutually compatible as regards to crystal growth.

Growth can be carried out over a thickness E that is sufficient, after removing graphite substrate 2, to provide a part made of SiC (or AlN or GaN) and that is sufficiently rigid to be manipulated. Thickness is preferably in the range of about 100 μm to 200 μm, for example. The grown layer can then either serve as a growth seed after introduction into a sublimation furnace, using known techniques, or it can itself be used as a wafer.

Growth can also be carried out over several hours to attain a thickness E of a conventional ingot, namely several millimeters, for example between 1 mm and 10 mm in thickness. After growth, the ingot can be detached from its graphite support, cored, oriented using X rays, and cut into slices to generate useful wafers. If desired, to avoid growth on a non-circular portion or outside a desired circular area, the substrate 2 can also be cored prior to growth.

This produces an ingot 24 (FIG. 6), which may be cylindrical of any diameter. The ingot 24 may have a large diameter such as D, such as of over 100 mm, and preferably has a with low defect density, such as of less than 1 cm⁻², preferably in the range of about 1 cm⁻² to 10 cm⁻² in the case of SiC micropipes, or less about than 10⁴ cm⁻², and more preferably less than about 10³ cm⁻² in the case of AlN or GaN dislocations.

It should be noted that the diameter of the ingot 24 referred to is the diameter of a circular section thereof, preferably substantially perpendicular to the direction of extension or growth of the ingot (this direction is perpendicular to the plane of films 4 in FIG. 5). If the ingot 24 is not entirely cylindrical, the diameter referred to can be a maximum dimension measured in a cross section of the ingot substantially perpendicular to that same extension or growth direction or parallel to the plane of the films 4.

During thick growth, it is typically not necessary to monitor radial temperature gradients tightly such as to within one degree, nor to widen the crystal, which step could be difficult to control. The desired final diameter D is determined by the surface area covered by the thin films 10 initially transferred to the graphite support 2. Thus, crystal growth is optimized.

The invention can thus generate a growth seed, preferably a large seed (4 inches, 6 inches, 8 inches, or greater in diameter, or 100 mm, 150 mm, 200 mm, or greater in diameter) and optionally control its crystalline quality by selecting good quality thin films. As shown in FIG. 5, the first substrate 2 of this embodiment is larger in surface area than the arranged layer 10, which is larger than the cross-section or surface area of the ingot 20 grown thereon, with each of these surfaces overlapping.

This technique makes it possible to produce monocrystalline polytype 4H, 6H, and 3C SiC ingots, for example, in diameters of 100 mm or more. The production of the monocrystalline SiC ingots then makes it possible to fabricate SiC wafers on which electronic or optoelectronic components can be fabricated, after cutting the SiC material into wafers 26 and typically after successive polishing of the wafers. Monocrystalline polytype 6H SiC substrates obtained by the method described above can then be used for epitaxial growth of nitrides, such as AlN, GaN, AlGaN, and InGaN.

LED (light emitting diode) type optoelectronic components or laser diodes emitting at short wavelengths of the visible spectrum (blue, ultraviolet), which are currently produced on 2 inch diameter substrates, can thus henceforth be produced on high purity substrates that are larger (such as 100 mm or more) in the present invention. Polytype 4H SiC substrates can be used for fabricating electronic power components such as Schottky diodes or MOS transistors or power FETs. These substrates are used as substrates for epitaxial SiC growth, with a view to fabricating the power components. Here again, the substrates of the invention, such as with a diameter of 100 mm or more and with a defect or micropipe density of at most 1 cm⁻², can increase the fabrication yields of all of these components.

Thus, the method of the invention can produce crystals of any diameter, including large diameter crystals (at least 100 mm), preferably with a defect density of less than 1 cm⁻², by bonding and transferring thin monocrystalline films onto a substrate or other support, and then by crystal growth of the assembly. The surface area of the assembly can be, for example, at least equal to that of the surface covered by a substrate with a diameter of 100 mm.

In embodiments in which a region of weakness is produced, for example, to detach the assembled crystal films that are associated with the first substrate from the donor substrate, the technique known as SMART-CUT® can be employed, as mentioned above. In example of this technique, before bonding the donor substrate with the first substrate, atomic species, such as hydrogen or helium ions, are implanted in the donor substrate to produce the region of weakness at a depth close to, at, or around the depth of the implantation. Alternatively, the region of weakness can comprise a weak interface between the film and the remainder of the donor wafer by forming at least one porous layer by anodization or by another pore-forming technique, for example, as described in document EPO 849788 A2.

Energy is supplied to the region of weakness after bonding the donor substrate to the first substrate. The energy can be supplied by heat or mechanical treatment or by another method, and is sufficient to detach the film from the remainder of the donor wafer in the region of weakness. Additionally, the donor wafer can be subjected to heat treatment during or after the implantation to further weaken the region of weakness.

The crystal that is bonded with the first substrate can be thinned instead or additionally by a chemical and/or chemical-mechanical material removal process. In one technique, the crystal including the film bonded to the first substrate is etched to retain only a thin portion of the crystal to define the film. Wet etching using etching solutions, or dry etching, such as plasma etching or sputtering, can be employed to remove material. The etching operations may be purely chemical, electro chemical, or photo electro chemical, or a combination of these. Additionally, the etching operations can be proceeded, followed, or accompanied by a mechanical operation, such as lapping, polishing, mechanical etching, or sputtering of atomic species. If an etching operation is accompanied by a mechanical operation, preferably the mechanical operation comprises polishing, optionally combined with the action of a mechanical abrasive in a CMP process. Etching in mechanical operations can also be performed on the film that is bonded with the first substrate prior to growing of the grown layer, such as ingot 20, or can be performed on the surface of the grown layer after it is grown.

A surface finishing technique can be carried out on the surface of the films that are bonded to the substrate in the arranged layer, or to the surface of the grown layer after growing. The surface finishing techniques can include, for example, selective chemical etching, CMP polishing, a heat treatment, or other smoothing operation. A finishing step such as an annealing operation can be carried out to strengthen the bond between the arranged layer of films and the first substrate.

The invention is also applicable to growing ingots of materials, preferably SiC, AlN, or GaN, synthesized by high temperature sublimation techniques, for which the enlarging the ingot during growth is normally complex or otherwise undesirable.

While illustrative embodiments of the invention are disclosed herein, it will be appreciated that numerous modifications and other embodiments may be devised by those skilled in the art. Therefore, it will be understood that the appended claims are intended to cover all such modifications and embodiments that come within the spirit and scope of the present invention.

What is claimed is:

1. A method of producing a crystal, comprising:
arranging and associating a plurality of layer segments of a first monocrystalline material on a first substrate to form an assembled layer comprising the segments; and
growing a layer of monocrystalline material on the assembled layer using the layer segments as seed material to form a grown monocrystalline material as the crystal.

2. The method of claim 1, wherein the grown monocrystalline material is the same material as the first monocrystalline material.

3. The method of claim 1, wherein the grown monocrystalline material is of a different monocrystalline material that is compatible with the first monocrystalline material.

4. The method of claim 1, wherein the layer segments comprise films.

5. The method of claim 1, wherein the first substrate has a face on which the assembled layer is disposed, the face having a width of at least about 100 mm and a surface area of at least about 75 cm².

6. The method of claim 1, wherein the layer segments are bonded to the first substrate.

7. The method of claim 1, further comprising associating at least one donor substrate of the first material on the first substrate and thinning the at least one associated donor substrate to provide the arranged and associated layer segments.

8. The method of claim 7, further comprising:
forming a region of weakness in the donor substrate; and
detaching a layer segment from the associated donor substrate at the region of weakness to thin the donor substrate.

9. The method of claim 8, wherein the region of weakness is produced by forming a porous zone in the donor substrate.

10. The method of claim 8, wherein the region of weakness is formed by implanting atomic species into the donor substrate.

11. The method of claim 7, wherein the donor substrate is thinned by polishing or etching.

12. The method of claim 1, further comprising associating at least one of the layer segments with a second substrate, wherein the layer segments are arranged and associated with the first substrate while associated with the second substrate.

13. The method of claim 12, further comprising removing the second substrate from the layer segment when the segment is associated with the first substrate.

14. The method of claim 12, wherein the second substrate comprises silicon dioxide.

15. The method of claim 1, wherein the grown monocrystalline layer is grown by sublimation.

16. The method of claim 1, wherein the grown monocrystalline layer is grown by high temperature thick epitaxy.

17. The method of claim 1, wherein the first microcrystalline material comprises silicon carbide with a micropipe density of less than about 10 cm⁻².

18. The method of claim 1, wherein the first monocrystalline material comprises aluminum nitride or gallium nitride with a dislocation density of less than about 10⁴ cm⁻².

19. The method of claim 1, wherein the first monocrystalline material comprises silicon carbide polytype 6H, 4H, or 3C.

20. The method of claim 1, wherein the grown layer is grown to provide a thickness of the grown monocrystalline material between about 50 μm and 10 mm.

21. The method of claim 1, wherein the first substrate comprises graphite.

22. The method of claim 1, wherein the thickness of the assembled layer is between about 0.1 μm and 1.5 μm.

23. The method of claim 1, wherein the arranged layer segments have a same crystal orientation.

24. A crystal made of monocrystalline material and encompassing a diameter of at least about 100 mm and a thickness of less than about 10 mm.

25. The crystal of claim 24, wherein the thickness is less than about 1 mm.

26. The crystal of claim 24, wherein the thickness is greater than about 100 μm.

27. The crystal of claim 24, wherein the monocrystalline material is silicon carbide with a micropipe density of less than about 1 cm⁻².

28. The crystal of claim 24, in which the monocrystalline material is silicon carbide polytype 6H, 4H, or 3C.

29. The crystal of claim 24, wherein the monocrystalline material is aluminum nitride or gallium nitride having a dislocation density is less than about 10⁴ cm⁻².

30. A crystalline wafer, comprising:
a first substrate; and
an assembled layer comprising a plurality of layer segments arranged and associated with the first substrate in a same crystal orientation for growing thereon a layer of monocrystalline material.

31. The wafer of claim 30, wherein the layer segments comprise silicon carbide, aluminum nitride, gallium nitride, aluminum gallium nitride, or indium gallium nitride.

32. The wafer of claim 30, further comprising a grown layer of monocrystalline material grown on the assembled layer.
